(19) United States
(12) Patent Application Publication
(10) Pub. No.: US 2014/0117412 A1
(43) Pub. Date: May 1, 2014

(54) Heterojunction Transistor and Manufacturing Method Therefor

(71) Applicant: INFINEON TECHNOLOGIES AG, Neubiberg (DE)

(72) Inventor: Wolfgang Werner, Munich (DE)

(73) Assignee: INFINEON TECHNOLOGIES AG, Neubiberg (DE)

(21) Appl. No.: 13/666,625

(22) Filed: Nov. 1, 2012

(51) Int. Cl. H01L 29/737; H01L 29/66

(52) U.S. Cl. CPC H01L 29/7371; H01L 29/66242
USPC 257/197; 438/312

(57) ABSTRACT

A heterojunction transistor including a semiconductor body is provided. The semiconductor body includes: a base region of a semiconductor material having a first band-gap, the base region being of a first conductivity type; a collector region of a semiconductor material having a second band-gap which is larger than the first band-gap by at least about 1 eV, the collector region being of a second conductivity type and forming a first heterojunction with the base region; and an emitter region of a semiconductor material having a third band-gap which is larger than the first band-gap by at least about 1 eV, the emitter region being of the second conductivity type and forming a second heterojunction with the base region. Further, a method for producing a heterojunction transistor is provided.

### TECHNICAL FIELD

Embodiments of the present invention relate to heterojunction semiconductor transistors, in particular to power transistors, and to related methods for producing heterojunction semiconductor transistors.

### BACKGROUND

Semiconductor transistors, in particular field-effect controlled switching devices such as a Junction Field Effect Transistor (JFET), a Metal Oxide Semiconductor Field Effect Transistor (MOSFET) and an Insulated Gate Bipolar Transistor (IGBT) have been used for various applications including but not limited to use as switches in power supplies and power converters, electric cars, air-conditioners, and even stereo systems. In particular for power transistors capable of switching large currents and/or operating at higher voltages low power loss are often desired.

Wide band-gap compound materials such as silicon carbide (SiC) have a high breakdown field strength and high critical avalanche field strength. Accordingly, the doping of the semiconductor regions can, in comparison to silicon (Si) semiconductor regions, be higher at given rated blocking voltage. This reduces the on-state resistance Ron of the device and makes SiC attractive for power applications and high voltage applications, respectively.

So far, MOSFETs and normally-on JFETs have been realized in SiC. However, a negative gate voltage is required to switch normally-on JFETs off. The on-state resistance Ron of SiC-MOSFETs is mainly determined by the channel conductivity, which is about 10 times lower than the channel conductivity of Si-MOSFETs. Furthermore, injection of minority charge carriers into the drift region of SiC-JFETs and SiC-MOSFETs used as transistors of driver circuits for an inductive load typically results in significant losses, in particular at higher switching speeds.

Accordingly, there is a need to improve wide band-gap semiconductor transistors.

### SUMMARY

According to an embodiment of a heterojunction transistor, the heterojunction transistor includes a semiconductor body. The semiconductor body includes: a base region of a semiconductor material having a first band-gap, the base region being of a first conductivity type; a collector region of a semiconductor material having a second band-gap which is larger than the first band-gap by at least about 1 eV, the collector region being of a second conductivity type and forming a first heterojunction with the base region; and an emitter region of a semiconductor material having a third band-gap which is larger than the first band-gap by at least about 1 eV. The emitter region is of the second conductivity type and forms a second heterojunction with the base region.

According to an embodiment of a heterojunction transistor, the heterojunction transistor includes: a base region of a first semiconductor material of a first conductivity type having a first band-gap, the first semiconductor material having one of a diamond cubic crystal structure, a polycrystalline structure and an amorphous structure; a collector region of a monocrystalline semiconductor material having a second band-gap which is larger than the first band-gap and a non-diamond cubic crystal structure, the collector region being of a second conductivity type and forming a first heterojunction with the base region; and an emitter region of a monocrystalline semiconductor material having a third band-gap which is larger than the first band-gap and a non-diamond cubic crystal structure. The emitter region is of the second conductivity type and forms a second heterojunction with the base region.

According to an embodiment of a heterojunction transistor, the heterojunction transistor includes a semiconductor body having a main surface. The semiconductor body includes in a cross-section which is substantially perpendicular to the main surface: a first base region of a semiconductor material having a first band-gap, the first base region being of a first conductivity type; a collector region of a semiconductor material having a second band-gap which is larger than the first band-gap by at least about 1 eV, the collector region being of a second conductivity type, extending to the main surface and forming a first heterojunction with the first base region; and a first emitter region of a semiconductor material having a third band-gap which is larger than the first band-gap by at least about 1 eV. The first emitter region is of the second conductivity type, extends to the main surface, and forms a second heterojunction with the first base region.

According to an embodiment of a method for producing a heterojunction transistor, the method includes: providing a wafer comprising a wide-band gap layer of a second conductivity type; depositing a first semiconductor material of a first conductivity type having a band-gap which is smaller than a band-gap of the wide-band gap layer by at least 1 eV on a surface of the wide-band gap layer to form a base region which forms a first heterojunction with the wide-band gap layer; and forming a second heterojunction between the base region and a wide-band gap semiconductor region having a band-gap which is larger than the band-gap of the base region by at least 1 eV.

Those skilled in the art will recognize additional features and advantages upon reading the following detailed description, and upon viewing the accompanying drawings.

### BRIEF DESCRIPTION OF THE DRAWINGS

The components in the figures are not necessarily to scale, instead emphasis being placed upon illustrating the principles of the invention. Moreover, in the figures, like reference numerals designate corresponding parts. In the drawings:

FIG. 1 illustrates a cross-section through a semiconductor body of a semiconductor transistor according to an embodiment;

FIG. 2 illustrates a vertical cross-section through a semiconductor body of a semiconductor transistor according to an embodiment;

FIG. 3 illustrates a vertical cross-section through a semiconductor body of a semiconductor transistor according to an embodiment; and

FIG. 4 illustrates a vertical cross-section through a semiconductor body of a semiconductor transistor according to an embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a first or main surface of a semiconductor substrate or body. This can be for instance the surface of a wafer or a die.

The term “vertical” as used in this specification intends to describe an orientation which is substantially arranged perpendicular to the first surface, i.e. parallel to the normal direction of the first surface of the semiconductor substrate or body.

In this specification, a second surface of a semiconductor substrate of semiconductor body is considered to be formed by the lower or backside surface while the first surface is considered to be formed by the upper, front or main surface of the semiconductor substrate. The terms “above” and “below” as used in this specification therefore describe a relative location of a structural feature to another structural feature with consideration of this orientation.

In this specification, p-doped is referred to as first conductivity type while n-doped is referred to as second conductivity type. Alternatively, the semiconductor devices can be formed with opposite doping relations so that the first conductivity type can be n-doped and the second conductivity type can be p-doped. Furthermore, some Figures illustrate relative doping concentrations by indicating “−” or “+” next to the doping type. For example, “n⁻” means a doping concentration which is less than the doping concentration of an “n”-doping region while an “n⁺”-doping region has a larger doping concentration than the “n”-doping region. However, indicating the relative doping concentration does not mean that doping regions of the same relative doping concentration have to have the same absolute doping concentration unless otherwise stated. For example, two different n⁺-doping regions can have different absolute doping concentrations. The same applies, for example, to an n⁺-doping and a p⁺-doping region.

Specific embodiments described in this specification pertain to, without being limited thereto, to semiconductor devices, in particular to heterojunction transistors and manufacturing methods therefor. It is to be understood that the heterojunction transistor of the present application is applicable to both npn-type and pnp-type.

The term “heterojunction” as used in this specification intends to describe an interface between two layers or regions of a semiconductor material with different crystal structure. These semiconducting materials have typically different band gaps.

Typically, the semiconductor device is a power semiconductor device having an active area with a plurality of transistor-cells for carrying and/or controlling a load current between two load metallization. Furthermore, the power semiconductor device may have a peripheral area with at least one edge-termination structure at least partially surrounding an active area of transistor-cells when seen from above.

The term “power semiconductor device” as used in this specification intends to describe a semiconductor device on a single chip with high voltage and/or high current switching capabilities. In other words, power semiconductor devices are intended for high current, typically in the Ampere range and/or high voltages, typically above 100 V, more typically above 400 V.

In the context of the present specification, the terms “in ohmic contact”, in resistive electric contact” and “in resistive electric connection” intend to describe that there is an ohmic current path between respective elements or portions of a semiconductor device at least when no voltages or only low probe voltages are applied to and/or across the semiconductor device. Likewise, the terms in low ohmic contact, “in low resistive electric contact” and “in low resistive electric connection” intend to describe that there is a low resistive ohmic current path between respective elements or portions of a semiconductor device at least when no voltages are applied to and/or across the semiconductor device. Within this specification the terms “in low ohmic contact”, “in low resistive electric contact”, “electrically coupled”, and “in low resistive electric connection” are used synonymously. In some embodiments, the resistivity of a low resistive current path between respective elements or portions of a semiconductor device which is low when low voltages are applied to and/or across the semiconductor device, for example a probe voltage of less than one or a few volts, becomes high above a threshold voltage, for example due to depleting a semiconductor region forming at least a part of the current path.

In the context of the present specification, the term “metallization” intends to de-scribe a region or a layer with metallic or near metallic properties with respect to electric conductivity. A metallization may be in contact with a semiconductor region to form an electrode, a pad and/or a terminal of the semiconductor device. The metallization may be made of and/or comprise a metal such as Al, Ti, W, Cu and Co but may also be made of a material with metallic or near metallic properties with respect to electric conductivity such as highly doped n-type or p-type poly-Si, TiN or an electrically conductive silicide such as TaSi₂, TiSi₂, PtSi, CoSi₂, WSi₂ or the like. The metallization may also include different electrically conductive materials, for example a stack of those materials.

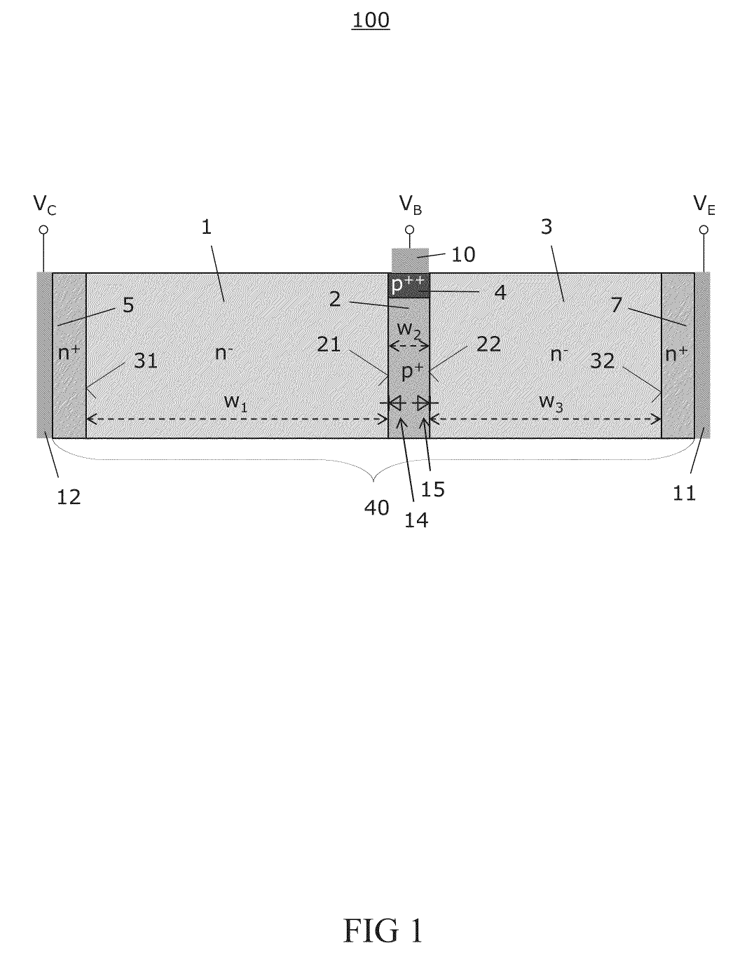

With reference to FIG. 1, embodiments of a heterojunction transistor 100 are explained. FIG. 1 illustrates a schematic cross-section through a semiconductor body 40 of the semiconductor transistor 100. In the exemplary embodiment, the semiconductor body 40 includes a first, a third, a fifth, and a seventh semiconductor region 1, 3, 5, 7 of the n-doping type which typically form a collector region 1, an emitter region 3, a collector contact region 5 and an emitter contact region 7, respectively. The semiconductor body 40 further includes a second and a fourth semiconductor region 2, 4 of the p-doping type which typically form a base region 2 and a base contact region 4, respectively. The doping relations may however also be reversed.

Typically, the base contact region 4 is higher doped than the base region 2 and is in ohmic contact with a base metallization 10. Accordingly, the base region 2 is also in ohmic contact with the base metallization 10. Furthermore, the high doping gradient between the base region 2 and the base contact region 4 facilitates that electrons in the base region 2 do not flow to the base metallization 10 during normal operation.

Typically, the collector contact region 5 is higher doped than the collector region 1, forms a first interface 31, i.e. a homojunction, with the collector region 1 and is in ohmic contact with a collector metallization 12. Accordingly, the collector region 1 is also in ohmic contact with the collector metallization 12.

In the exemplary embodiment, the emitter contact region 7 is higher doped than the emitter region 3, forms a second interface 32 with the emitter region 3 and is in ohmic contact with an emitter metallization 11. Accordingly, the emitter region 3 is also in ohmic contact with the emitter metallization 11.

In other embodiments, the maximum doping concentration of the emitter region 3 is high enough at least close to the emitter metallization 11 to form an ohmic contact with the emitter metallization 11. In these embodiments, the emitter contact region 7 may be omitted.

According to an embodiment, the collector region 1 forms a first heterojunction 21 with the base region 2 and the emitter region 3 forms a second heterojunction 22 with the base region 2. Accordingly, the semiconductor structure 100 forms a three-terminal heterojunction transistor with two heterojunctions 21, 22. Furthermore, the band-gap of the base region 2 is lower than the band-gap of the emitter region 3 and lower than the band-gap of the collector region 1. This typically also applies to the base contact region 4 which forms a homojunction with the base region 2. The base region 2 and the base contact region 4 may be made of the same semiconductor material.

Due to the heterojunctions 21, 22, the injection of minority charge carriers from the base region 2 into the collector region 1 and from the base region 2 into the emitter region 3 is reduced. Accordingly, device performance such as switching losses of the heterojunction transistor 100 may be improved compared to bipolar heterojunction transistors with only one heterojunction, for example a bipolar heterojunction transistor having a AlGaAs-emitter region (aluminum gallium arsenide) forming a heterojunction with a GaAs-base region (gallium arsenide) adjoining a GaAs collector region or a similar bipolar SiGe/Si heterojunction transistor (silicon-germanium/silicon) which are optimized for high speed low-voltage applications.

According to an embodiment, the band-gaps and/or the crystal structures of the collector region 1, the base region 2 and the emitter region 3 are chosen such that substantially no minority charge carriers are injected from the base region 2 into the collector region 1 and the emitter region 3 during normal device operation, i.e. that, in the exemplary embodiment illustrated in FIG. 1, holes are substantially not injected from the p-type base region 2 into the n-type collector region 1 and the n-type emitter region 3 during normal device operation. Accordingly, minority charge carriers do not substantially contribute to the current, typically to less than a fraction of about 10⁻⁶ of the current between the collector region 1 and the emitter region 3. This further improves device operation compared to known bipolar heterojunction transistor in which minority charge carriers substantially contribute to the current in the emitter region, the base region and the collector region. Note that the heterojunction transistors described herein are neither pure unipolar nor pure bipolar transistors.

In an embodiment, the base region 2 has a diamond cubic crystal structure, a polycrystalline structure or an amorphous structure, while the collector region 1 and the emitter region 3 are made of a monocrystalline semiconductor material having a non-diamond cubic crystal structure. For example, the semiconductor material of the base region 2 may be Ge, Si or SiₓGe₁₋ₓ, while the collector region 1 and the emitter region 3 are made of a monocrystalline semiconductor material having a Wurzite crystal structure such as 4H-SiC, 6H-SiC, and GaN (gallium nitride), a Zinc blende crystal structure such as 3C-SiC, GaN, GaAs, GaAlAs or a rhombohedral crystal structure such as 15R-SiC. Note that compound semiconductor materials such as SiC and GaN may exist in polytypes of different crystal structure. Note further that the manufacturing of heterojunction transistors with a non-monocrystalline base region 2, for example a poly-Si base region 2, may even be simpler than the manufacturing of bipolar heterojunction transistors having only semiconductor regions of the same crystal structure. This is particularly the case in embodiments in which the collector region 1 and the emitter region 3 are made of the same semiconductor material, for example 4H-SiC. In these embodiments, the heterojunctions 21, 22 may be formed by depositing of poly-Si.

According to an embodiment, both the band-gap of the collector region 1 and the band-gap of the emitter region 3 are higher than the band-gap of the base region 2 by at least about 1 eV. For example, the collector region 1 and the emitter region 3 may be made of a wide band-gap material such as SiC and GaN having band-gaps above about 2.26 eV (3C-SiC), while the base region 2 may be made of Ge, Si or SiₓGe₁₋ₓ having comparatively low band-gaps of about 0.67 eV (Ge), 1.12 eV (Si) and in-between 0.67 eV and 1.12 eV (SiₓGe₁₋ₓ).

Note that the collector region 1 and the emitter region 3 may be made of the same or different semiconductor materials. For sake of clarity, the heterojunction transistors are in the following explained with regard to embodiments in which the collector region 1 and the emitter region 3 are made of the same semiconductor material, i.e. the same chemical element or compound and the same crystal structure (polytype). For the same reason, the collector region 1 and the emitter region 3 are assumed to made of SiC, more particularly 4H-SiC and the base region 2 is assumed of be made of Si in the following. This is however not to be understood as limiting.

The heterojunction transistors described herein may electronically be considered as two anti-serially connected heterojunction diodes 14, 15 which are monolithically integrated in a semiconductor device.

For 4H-SiC/Si heterojunction diodes 14, 15 having a p⁺-zone of Si forming a heterojunction with an n⁻-zone of 4H-SiC the following properties are known. The breakdown voltage is for same doping concentrations about the same compared to a homojunction pn-SiC diode. The leakage current is comparable to a Schottky diode. For example, the leakage current of the heterojunction diodes 14, 15 may be about 2×10⁻⁵ A/cm² at a reverse biasing of about 1000 V for a diode of 1600 V rated blocking voltage. During forward biasing, no holes are injected into the n⁻-zone. Similar as for Schottky diodes, the electron current is provided by the p⁺-zone. Furthermore, the density of the electrons of the p⁺-zone at the heterojunction (pn-junction) is tuneable by the voltage drop across the heterojunction. Similar as for bipolar transistors, the electrons of the p⁺-zone at the pn-junction is during reverse biasing with 100 V about 10⁷ cm⁻³ and in forward bias of 1.2 V about 10¹⁶ cm⁻³ (at given doping concentrations of 10²⁰ cm⁻³ for the p⁺-zone and 10¹⁶ cm⁻³ for the n⁻-zone).

For a 4H-SiC/Si/4H-SiC heterojunction transistor 100, the following properties are to be expected. If the heterojunction diode 15 is operated in forward mode, for example at a base-emitter voltage V_{BE}=V_{B}−V_{E} of about 1.2 V and the other heterojunction diode 14 is operated in reverse mode, a diffusion current will flow through the base region 2 which is due to the large ratio of electron concentration between the emitter side and the collector side of about 10⁹. The diffusion current depends on the base-emitter voltage V_{BE}, the width w₂ of the base region 2 and the electron concentration at the emitter side. For a typical width w₂ of the base region 2 between the emitter region 3 and the collector region 1 of about 0.5 μm, the recombination of electrons and holes is neglectable in the base region 2. This results in the following advantages. The heterojunction transistor 100 is a normally-off switching device. The control voltages are in a low range of about 0 V to about 1.5 V. The static electric control power is almost zero. This is because no or almost no hole current is injected into the emitter region 3 and the collector region 1 during the off-state and because only a small collector-base reverse leakage current flows through the base region 2 during the off-state. The dynamic electric control power maybe substantially lower compared to MOSFETs and JFETs. This is because of the comparable input capacitances and the fact that the heterojunction transistor 100 operates, due to the exponential input characteristics, at full level already at low voltages of about 1.5 V. Note that the heterojunction transistor 100 is—contrary to bipolar transistors—voltage controlled. Furthermore, the heterojunction transistor 100 may be operated in a saturated mode in which the heterojunction 21 between the collector region 1 and the base region 2 (heterojunction diode 14) is forwardly biased. In this mode, the voltage drop between the collector metallization 12 and he emitter metallization 11 may be as low as about 0.1 V. Contrary to a bipolar transistor, no minority charge carriers are injected into the collector region 1. Accordingly, switching losses of the heterojunction transistor 100 are not increased when the saturated mode is used. Furthermore, even when the heterojunction transistor 100 is used to drive an inductive load, which may result in negative collector voltages V_{C} (with V_{B}=V_{E}=0) during switching-off, no minority charge carriers are injected into the collector region 1 in the saturation mode. Accordingly, an additional free-wheeling diode as used for MOSFETS and JFETs is not required. Even further, the heterojunction transistor 100 may be realized as a reverse blocking transistor if the maximum doping concentration of the emitter region 3 is low enough, for example lower than about 10¹⁷ cm⁻³, more typically lower than about 10¹⁶ cm⁻³. Due to using wide band-gap materials for the collector region 1 and the emitter region 3, both high rated blocking voltages and low on-resistance may be achieved.

The maximum doping concentration of the base region 2 is typically in a range from about 10¹⁸ cm⁻³ to about 10²⁰ cm⁻³.

The maximum doping concentration of the collector region 1 and the emitter region 3 may both be in a range from about 10¹⁵ cm⁻³ to about 10¹⁷ cm⁻³. In other embodiments the maximum doping concentration of the emitter region 3 may be higher, in a range from about 10¹⁸ cm⁻³ to about 10²⁰ cm⁻³. In these embodiments, a distance w₃ between the second heterojunction 22 and the second interface 32 may be small and may even be zero or substantially zero.

According to an embodiment, a distance w₁ between the first heterojunction 21 and the first interface 31 is larger than the distance w₃ between the second heterojunction 22 and the second interface 32. Note that the distances w₁, w₃ typically correspond to a length of a shortest current path or a shortest electric field line between the respective heterojunctions 21, 22 and interfaces 31, 32. In the exemplary embodiment illustrated in FIG. 1, the distances w₁, w₃ are given by the shortest geometric distance between the first heterojunction 21 and the first interface 31 and between the second heterojunction 22 and the second interface 32, respectively. Typically, the distance w₃ is in a range from about 0 μm to about 5 μm.

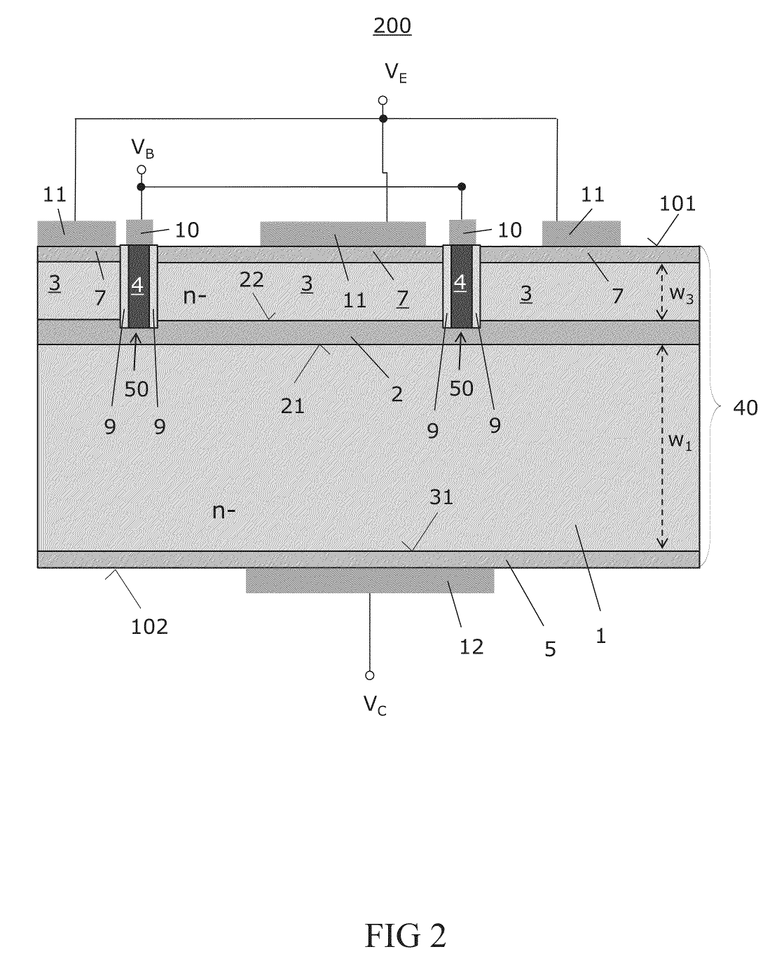

With reference to FIG. 2, a heterojunction transistor 200 and embodiments of a method for forming the heterojunction transistor 200 are explained. The heterojunction transistor 200 is similar to the heterojunction transistor 100 explained above with regard to FIG. 1. The semiconductor body 40 of the heterojunction transistor 200 has a main surface 101 and a back surface 102 which is arranged opposite to the main surface 101. FIG. 2 illustrates a vertical cross-section through the semiconductor body 40, i.e. a cross-section which is substantially orthogonal to the main surface 101.

In the exemplary embodiment, the emitter metallization 11 and the base metallization 10 are arranged on the main surface 101, and the collector metallization 12 is arranged on the back surface 102. Furthermore, the first heterojunction 21 and the second heterojunction 22 are substantially parallel to the main surface 101.

The base region 2 is embedded in the semiconductor body 40 and contacted with the base metallization 10 via two exemplary contact trenches 50 which extend from the main surface 101 partly into the base region 2 and include a base contact region 4. Dielectric layers 9 are arranged on the sidewalls of the vertical trenches 50 so that the emitter regions 3 and emitter contact regions 7 are not in contact with the base contact region 4.

Typically, the heterojunction transistor 200 is a power transistor. In this embodiment, a plurality of vertical trenches 50 may be provided.

For manufacturing the heterojunction transistor 200, a wafer having an n-type wide-band gap layer 1 such as SiC may be provided. In the transistor to be manufactured, the wide-band gap layer 1 typically forms a collector region. Typically, the wafer further includes a higher doped collector contact region 5 forming a substantially plane interface 31 with the wide-band gap layer 1. Thereafter, a p-type first semiconductor material having a band-gap which is smaller than a band-gap of the wide-band gap layer 1 by at least 1 eV, for example Si, may be deposited on a surface of the wide-band gap layer 1 to form a base region 2 which forms a first heterojunction 21 with the wide-band gap layer 1. Thereafter, a second heterojunction 22 between the base region 2 and a wide-band gap semiconductor region 3 having a band-gap which is larger than the band-gap of the base region 2 by at least 1 eV, for example a SiC semiconductor region 3, is formed. This may also be done by deposition and an optional implantation process.

The first semiconductor material may be deposited as a non-monocrystalline region or layer 2 or as a monocrystalline region or layer 2.

In a typical embodiment, the first heterojunction 21 and the second heterojunction 22 are formed as Si/SiC-heterojunctions.

Thereafter, a higher doped emitter contact region of layer 7 of the wide-band gap semiconductor material may be formed on the semiconductor region 3. This may include a deposition process and/or an implantation process.

In further processes, vertical contact trenches 50 may be etched from the main surface 101 partly into the base region 2; dielectric layers 9 may be arranged on the sidewalls of the vertical trenches 51; and p-type base contact regions 4 may be formed in the contact trenches 50. The latter process may, for example, include depositing p-type poly-Si, using e.g. a low pressure chemical vapour deposition (LPCVD), and a subsequent CMP-process (Chemical Mechanical Polishing) or back-etching.

Thereafter, an emitter metallization 11 and a base metallization 10 may be formed on the main surface 101, and a collector metallization 12 may be formed on the back surface 102. Forming the emitter metallization 11 and the base metallization 10 typically includes at least one common deposition process and a masked etching process.

Note that the doping relations may also be reversed to form a pnp-heterojunction transistor, for example a p-4H-SiC/n-Si/p-4-SiC heterojunction transistor, instead of the npn-heterojunction transistor 200 illustrated in FIG. 2.

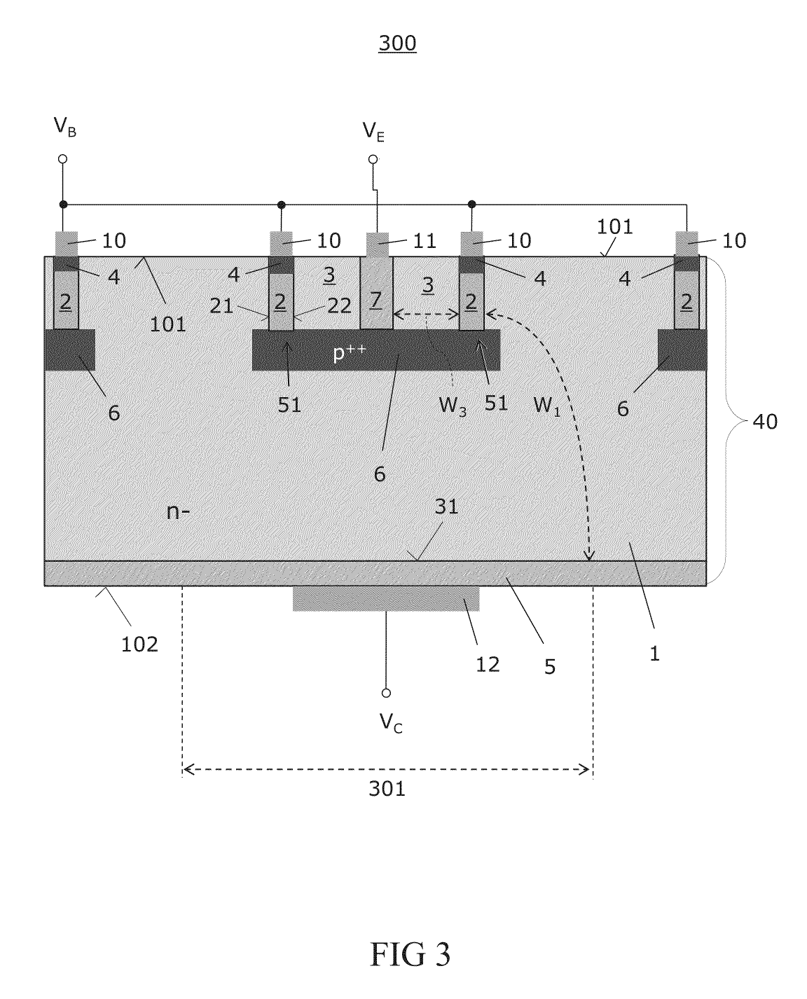

With reference to FIG. 3, a heterojunction transistor 300 and embodiments of a method for forming the heterojunction transistor 300 are explained. The heterojunction transistor 300 is similar to the heterojunction transistor 100 explained above with regard to FIG. 1. The semiconductor body 40 of the heterojunction transistor 300 has a main surface 101 and a back surface 102 which is arranged opposite to the main surface 101. FIG. 3 illustrates a vertical cross-section through the semiconductor body 40.

In the exemplary embodiment, the emitter metallization 11 and the base metallization 10 are arranged on the main surface 101, and the collector metallization 12 is arranged on the back surface 102. However, the first heterojunction 21 and the second heterojunction 22 are substantially perpendicular to the main surface 101.

Furthermore, the collector region 1, the emitter region(s) 3, the emitter contact region 7 and the base contact regions 4 extend to the main surface 101 in the exemplary embodiment.

In addition, highly doped p-type embedded semiconductor region(s) 6, which are in the following also referred to as screen region(s) 6, in contact with the base region(s) 2 are typically arranged below the emitter region(s) 3 and the emitter contact region 7 and between these regions 3, 7 and the collector region 1 to avoid an ohmic current path between the emitter metallization 11 and the collector metallization 12. The emitter contact region 7 typically extends to or partly into a respective screen region 6. The screen region(s) 6 may be made of the same semiconductor material as the collector region 1.

The heterojunction transistor 300 is typically a power semiconductor device which includes a plurality of unit cells 301. Typically, the unit cells 301 form a regular lattice.

For manufacturing the heterojunction transistor 300, a wafer having an n-type wide-band gap layer 1 such as SiC may be provided. In the transistor 300 to be manufactured, the wide-band gap layer 1 typically forms a collector region. Typically, the wafer further includes a higher doped collector contact region 5 forming a substantially plane interface 31 with the wide-band gap layer 1.

Thereafter, suitably doped p-type screen region(s) 6, base region(s) 4 and base contact regions 4 are typically formed. This may include one or more implantations and one or more processes of deposing the semiconductor material of the wide-band gap layer 1.

Thereafter, vertical trenches 51 may be etched from the main surface 101 to or partly into respective screen regions 6. Thereafter, a p-type first semiconductor material having a band-gap which is smaller than a band-gap of the wide-band gap layer 1 by at least 1 eV, for example Si, may be deposited in the vertical trenches 51 to form base regions 2 which form respective first heterojunctions 21 with the collector region 1 and respective second heterojunctions 22 with the emitter region 3. Furthermore, higher doped p-type base contact regions 4 are typically formed in upper portions of the vertical trenches 51. This may include a further process of depositing and/or an implantation process. Residual deposited semiconductor material is typically removed from the main surface 101 by back-etching and/or a CMP-process.

Thereafter, an emitter metallization 11 and a base metallization 10 may be formed on the main surface 101, and a collector metallization 12 may be formed on the back surface 102.

Note again that the doping relations may also be reversed.

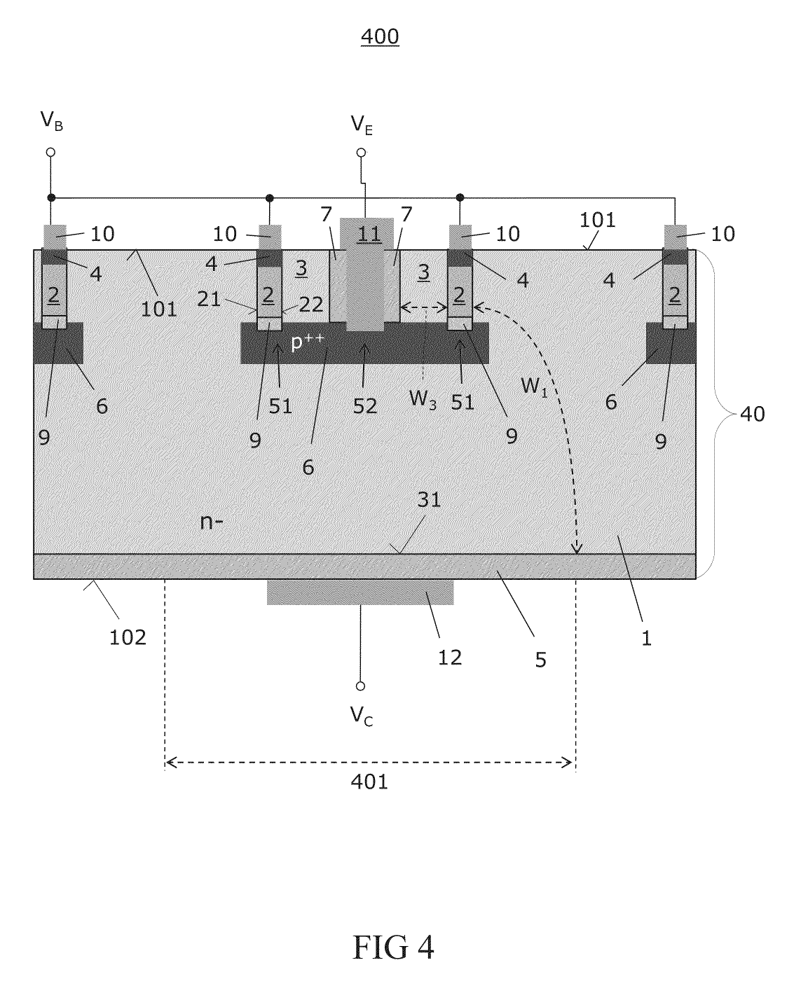

With reference to FIG. 4, a heterojunction transistor 400 and embodiments of a method for forming the heterojunction transistor 400 are explained. The heterojunction transistor 400 is similar to the heterojunction transistor 300 explained above with regard to FIG. 3. However, the screen layer(s) 6 are not in ohmic contact with the base metallization 10 but rather with the emitter metallization 11. Accordingly, the base regions 2 are, in a blocking mode, screened from the electric field. In so doing, the latch-up stability of the heterojunction transistor 400 is improved.

In the exemplary embodiment, a dielectric region 9 is arranged in a lower portion of the vertical trenches 51, i.e. between the base region 2 and the screen layer 6.

According to an embodiment, a further vertical trench 52 extends from the main surface 101 through the emitter contact region 7 and to or partly into the screen layer 6. The further vertical trench 52 is filled with a conductive plug that may be formed by a lower portion of the emitter metallization 11. In other embodiments, the conductive plug is made of a different highly conductive material.

The heterojunction transistor 400 is typically also a power semiconductor device which includes a plurality of unit cells 401. Typically, the unit cells 401 form a regular lattice.

The manufacturing of the heterojunction transistor 400 may also be similar as explained above with regard to FIG. 3. However, a dielectric region 9 is formed in a bottom portion of the vertical trenches 51 prior to forming the body regions 2 and the heterojunctions 21, 22, respectively.

Furthermore, a further trench 52 is etched from the main surface 101, through the emitter contact region 7 and to or partly into the screen layer 6 prior to forming the emitter metallization 11 and the conductive plug, respectively.

A heterojunction transistor 300 and 400 explained above with regard to FIGS. 3 and 4 have in common that the semiconductor body 40 has a main surface 101 and that the semiconductor body 40 includes, in a cross-section which is substantially perpendicular to the main surface 101, a first base region 2 of a semiconductor material having a first band-gap, the first base region 2 being of a first conductivity type; a collector region 1 of a semiconductor material comprising a band-gap which is larger than the first band-gap by at least about 1 eV, the collector region 1 being of a second conductivity type, extending to the main surface 101 and forming a first heterojunction 21 with the first base region 2; and a first emitter region 3 of a semiconductor material comprising a band-gap which is larger than the first band-gap by at least about 1 eV, the first emitter region being of the second conductivity type, extending to the main surface 101, and forming a second heterojunction 22 with the first base region 2. For example, the left base region 2 of the unit cells 301, 401 may be regarded as the first base region and the left emitter region 3 in FIGS. 3, 4 may be considered as the first emitter region 3.

According to an embodiment, the first heterojunction 21 and the second heterojunction 22 are substantially perpendicular to the main surface 101.

Typically, a second base region 2 of the first conductivity type, for example the right base region 2 of the unit cells 301, 401, also forms a heterojunction with the collector region 1. The second base region 2 and the first base region 2 are typically made of the same semiconductor material.

In this embodiment, a second emitter region 3 of the second conductivity type, for example the right emitter region 3 in FIGS. 3, 4, typically extends to the main surface 101 and forms a heterojunction with the second base region 2. The second emitter region 3 and the first emitter region 3 are typically made of the same semiconductor material.

According to an embodiment, an embedded semiconductor region 6 of the first conductivity type adjoins the collector region 1, the first emitter region 3 and the second emitter region 3. The embedded semiconductor region 6 and the collector region 1 are typically made of the same semiconductor material.

In the embodiment illustrated in FIG. 4, a conductive plug 11 is arranged between the second emitter region 3 and the first emitter region 3 and in ohmic contact with the second emitter region 3 and the first emitter region 3. Typically, the conductive plug 11 is in contact with the embedded semiconductor region 6.

Although various exemplary embodiments of the invention have been disclosed, it will be apparent to those skilled in the art that various changes and modifications can be made which will achieve some of the advantages of the invention without departing from the spirit and scope of the invention. It will be obvious to those reasonably skilled in the art that other components performing the same functions may be suitably substituted. It should be mentioned that features explained with reference to a specific figure may be combined with features of other figures, even in those cases in which this has not explicitly been mentioned. Such modifications to the inventive concept are intended to be covered by the appended claims.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A heterojunction transistor, comprising a semiconductor body comprising:
a base region of a semiconductor material comprising a first band-gap, the base region being of a first conductivity type;
a collector region of a semiconductor material comprising a second band-gap which is larger than the first band-gap by at least about 1 eV, the collector region being of a second conductivity type and forming a first heterojunction with the base region; and
an emitter region of a semiconductor material comprising a third band-gap which is larger than the first band-gap by at least about 1 eV, the emitter region being of the second conductivity type and forming a second heterojunction with the base region.

2. The heterojunction transistor of claim 1, wherein the collector region and the emitter region are made of the same semiconductor material.

3. The heterojunction transistor of claim 1, wherein the base region is made of a non-monocrystalline semiconductor material.

4. The heterojunction transistor of claim 1, wherein base region is made of a monocrystalline semiconductor material with a diamond cubic crystal structure.

5. The heterojunction transistor of claim 1, wherein the semiconductor material of the base region is selected from a group consisting of Ge, Si and SiₓGe₁₋ₓ.

6. The heterojunction transistor of claim 1, wherein at least one of the collector region and the emitter region is made of a monocrystalline semiconductor material having a crystal structure selected from a group consisting of a Wurzite crystal structure, a Zinc blende crystal structure and a rhombohedral crystal structure.

7. The heterojunction transistor of claim 1, wherein the semiconductor material of at least one of the collector region and the emitter region is selected from a group consisting of SiC, GaN and GaAs.

8. The heterojunction transistor of claim 1, wherein a maximum doping concentration of at least one of the base region and the emitter region is at least about 10¹⁸ cm⁻³.

9. The heterojunction transistor of claim 1, wherein a maximum doping concentration of at least one of the collector region and the emitter region is smaller than about 10¹⁷ cm⁻³.

10. The heterojunction transistor of claim 1, wherein the semiconductor body comprises a main surface and a back surface arranged opposite to the main surface, the semiconductor device further comprising at least one of an emitter metallization arranged on the main surface and in ohmic contact with the emitter region, and a collector metallization arranged on the back surface and in ohmic contact with the collector region, and wherein at least one of the first heterojunction and the second heterojunction is substantially perpendicular to the main surface.

11. The heterojunction transistor of claim 1, wherein the semiconductor body comprises a main surface and a back surface arranged opposite to the main surface, further comprising at least one of an emitter metallization arranged on the main surface and in ohmic contact with the emitter region, and a collector metallization arranged on the back surface and in ohmic contact with the collector region, and wherein at least one of the first heterojunction and the second heterojunction is substantially parallel to the main surface.

12. The heterojunction transistor of claim 1, wherein the semiconductor body comprises a main surface and a back surface arranged opposite to the main surface, and wherein the semiconductor body comprises, in a cross-section which is substantially perpendicular to the main surface, a plurality of base regions each of which forming a respective first heterojunction with the collector region.

13. The heterojunction transistor of claim 1, wherein the semiconductor body further comprises at least one of:
a base contact region of the first conductivity type adjoining the base region;
a collector contact region of the second conductivity type forming a first interface with the collector region; and
an emitter contact region of the second conductivity type forming a second interface with the emitter region and comprising a higher maximum doping concentration than the emitter region.

14. The heterojunction transistor of claim 13, wherein a distance between the first heterojunction and the first interface is larger than a distance between the second heterojunction and the second interface.

15. The heterojunction transistor of claim 14, wherein the distance between the second heterojunction and the second interface is substantially zero.

16. A heterojunction transistor, comprising:
a base region of a first semiconductor material of a first conductivity type comprising a first band-gap, the first semiconductor material comprising one of a diamond cubic crystal structure, a polycrystalline structure and an amorphous structure;
a collector region of a monocrystalline semiconductor material comprising a second band-gap which is larger than the first band-gap and a non-diamond cubic crystal structure, the collector region being of a second conductivity type and forming a first heterojunction with the base region; and
an emitter region of a monocrystalline semiconductor material comprising a third band-gap which is larger than the first band-gap and a non-diamond cubic crystal structure, the emitter region being of the second conductivity type and forming a second heterojunction with the base region.

17. The heterojunction transistor of claim 16, wherein the collector region and the emitter region are made of the same semiconductor material.

18. The heterojunction transistor of claim 16, wherein the second band-gap is larger than the first band-gap by at least about 1 eV, and wherein the third band-gap is larger than the first band-gap by at least about 1 eV.

19. The heterojunction transistor of claim 16, wherein the monocrystalline semiconductor material of the collector region comprises one of a Wurzite crystal structure, a Zinc blende crystal structure and rhombohedral crystal structure, and wherein the monocrystalline semiconductor material of the emitter region comprises one of a Wurzite crystal structure, a Zinc blende crystal structure and rhombohedral crystal structure.

20. The heterojunction transistor of claim 16, wherein the first semiconductor material is Si, and wherein the monocrystalline semiconductor material of at least one of the collector region and the emitter region is 4H-SiC.

21. The heterojunction transistor of claim 16, wherein the heterojunction transistor is an npn-transistor.

22. A heterojunction transistor, comprising a semiconductor body comprising a main surface, and in a cross-section which is substantially perpendicular to the main surface, the semiconductor body further comprises:
a first base region of a semiconductor material comprising a first band-gap, the first base region being of a first conductivity type;
a collector region of a semiconductor material comprising a second band-gap which is larger than the first band-gap by at least about 1 eV, the collector region being of a second conductivity type, extending to the main surface and forming a first heterojunction with the first base region; and
a first emitter region of a semiconductor material comprising a third band-gap which is larger than the first band-gap by at least about 1 eV, the first emitter region being of the second conductivity type, extending to the main surface, and forming a second heterojunction with the first base region.

23. The heterojunction transistor of claim 22, wherein in the vertical cross-section the semiconductor body further comprises at least one of:
a second base region of the first conductivity type forming a heterojunction with the collector region, the second base region and the first base region being made of the same semiconductor material;
a second emitter region of the second conductivity type extending to the main surface and forming a heterojunction with the second base region, the second emitter region and the first emitter region being made of the same semiconductor material; and
a conductive plug arranged between the second emitter region and the first emitter region and in ohmic contact with the second emitter region and the first emitter region.

24. The heterojunction transistor of claim 23, further comprising an embedded semiconductor region of the first conductivity type adjoining the collector region, the first emitter region and the second emitter region, the embedded semiconductor region and the collector region being made of the same semiconductor material.

25. The heterojunction transistor of claim 24, wherein the conductive plug is in ohmic contact with the embedded semiconductor region.

26. The heterojunction transistor of claim 22, further comprising at least one of:
a base metallization arranged on the main surface and in ohmic contact with at least the first base region;
an emitter metallization arranged on the main surface and in ohmic contact with at least the first emitter region; and
a collector metallization arranged on a back surface of the semiconductor body and in ohmic contact with the collector region.

27. A method for forming a heterojunction transistor, comprising:
providing a wafer comprising a wide-band gap layer of a second conductivity type;
depositing a first semiconductor material of a first conductivity type comprising a band-gap which is smaller than a band-gap of the wide-band gap layer by at least 1 eV on a surface of the wide-band gap layer to form a base region which forms a first heterojunction with the wide-band gap layer; and
forming a second heterojunction between the base region and a wide-band gap semiconductor region comprising a band-gap which is larger than the band-gap of the base region by at least 1 eV.

28. The method of claim 27, wherein the second heterojunction is formed by depositing the first semiconductor material.

29. The method of claim 27, wherein the second the heterojunction is formed by depositing a wide-band-gap semiconductor material on the base region.

30. The method of claim 27, wherein the first semiconductor material is deposited as a non-monocrystalline region.

31. The method of claim 27, wherein the first semiconductor material is deposited in a trench extending into the wide-band gap layer.
